(19) United States
(12) Patent Application Publication
(10) Pub. No.: US 2005/0255244 A1
(43) Pub. Date: Nov. 17, 2005

(54) Lifting glass substrate without center lift pins

(75) Inventors: Li Hou, Cupertino, CA (US); Quanyuan Shang, Saratoga, CA (US); Robert I. Greene, Fremont, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(73) Assignee: Applied Materials, Inc.

(21) Appl. No.: 11/188,375

(22) Filed: Jul. 25, 2005

Related U.S. Application Data
(62) Division of application No. 10/299,216, filed on Nov. 18, 2002.

(51) Int. Cl. C23C 16/00; H05H 1/24

(52) U.S. Cl. 427/248.1; 427/569

(57) ABSTRACT

A method for lifting a substrate from a susceptor. A plurality of lift pins is configured so that they support the substrate without contacting a central portion of the substrate. The processed substrate has a first dimension that is at least 500 millimeters and a second dimension that is at least 500 millimeters. Each lift pin in the plurality of lift pins is configured so that it supports the substrate from a point that is at least 120 millimeters from a center of the substrate. The plurality of lift pins is configured so that each side of the susceptor is supported by at least three lift pins. In some embodiments, a support member overlies at least a subset of the plurality of lift pins.

### CROSS-REFERENCE TO RELATED APPLICATIONS

This application is a divisional of co-pending U.S. patent application Ser. No. 10/299,216, filed Nov. 18, 2002. The aforementioned related patent application is herein incorporated by reference.

### BACKGROUND OF THE INVENTION

### FIELD OF THE INVENTION

Embodiments of the present invention generally relate to an improved method and apparatus for lifting a substrate from a susceptor. More specifically, the present invention relates to a method and apparatus that avoids the creation of discontinuity marks in the center region of the processed substrate

Plasma chemical vapor deposition (CVD) is a process in which various materials are deposited on a substrate in order to create a film. Generally, in a CVD process, the substrate is supported by a susceptor in a vacuum deposition process chamber and is heated to several hundred degrees Celsius during processing. Deposition gases are injected into the chamber, and a chemical reaction occurs, resulting in the deposition of a specific film on the substrate. Two deposition processes used in a CVD chamber include plasma enhanced CVD (PECVD) and thermally enhanced CVD. The CVD process is used to manufacture liquid crystal displays, flat panel displays, film transistors as well as other semiconductor devices.

A CVD susceptor is a mechanical part within the CVD chamber that functions as a ground electrode and supports the substrate in the processing chamber during deposition. The susceptor includes a substrate support plate mounted on a stem as well as a lift assembly for raising and lowering the substrate within the CVD processing chamber.

For commercial production, plasma CVD apparatus typically includes a lifting device for automatically transferring a substrate to a susceptor in a deposition chamber, and for lifting the processed substrates from the susceptor in order to remove the substrates from the deposition chamber. The lifting device includes lift pins for supporting the processed substrate when it is lifted from the susceptor.

FIG. 1A is a top plan view that shows an exemplary lift pin configuration in a CVD apparatus in accordance with the prior art. In FIG. 1A, the lift pins are configured so that there are two central lift pins 150 supporting a central region 140 of a substrate 160. Further, there are eight edge lift pins 110 supporting substrate 160 at the perimeter of the substrate. In the configuration shown in FIG. 1A, two edge pins 110 support the substrate near each of corner of substrate 160. FIG. 1B is a side cross-sectional view of FIG. 1A about line 1-1′ of FIG. 1A. FIG. 1B illustrates how lift pins 110 and 150 are positioned in holes (not shown) in a susceptor 166. During the CVD deposition processes, substrate 160 lies directly on susceptor 166. To separate substrate 160 from susceptor 166 after deposition has finished, either (i) lift pins 110 and 150 are raised through susceptor 166 (ii) or lift pins 110 and 150 remain fixed while susceptor 166 is lowered.

There are several drawbacks associated with the use of center lift pins 150 in conventional CVD systems. These drawbacks include the formation of discontinuity marks, also known as golf tee marks, where central lift pins contact the processed substrate. Another drawback with the operation of a conventional CVD apparatus is that films deposited on the substrate in the region directly supported by a central lift pin 150 are typically five to ten percent thinner and less dense than films deposited on other regions of the substrate.

FIG. 2 illustrates film thickness as a function of substrate position on a processed substrate. The film is a gate nitride film that was deposited using a conventional CVD apparatus. Region 205 represents the position where a center lift pin 150 directly supports processed substrate 160. The graph shows that the film deposited on processed substrate 160 is less thick in region 205 relative to areas outside of regions 205. Moreover, the deposition thickness uniformity for the processed substrate of FIG. 2 is 4.4 percent. Here, deposition thickness uniformity (thickness variation) is defined as:
(Max−Min)/(Max+Min)×100%
where Min is the thickness of the deposited film at a position within region 205 of substrate 160 and Max is the thickness of the deposited film at a position on substrate 160 that is outside of region 205 of substrate 160. A deposition thickness uniformity (thickness variation) of 4.4% at a center position in a substrate is not desirable.

FIG. 3 illustrates the wet etch rate in relation to substrate position for the same substrate used in FIG. 2. As in FIG. 2, region 205 represents the position where a center lift pin 150 directly supports processed substrate 160. The graph shows that, on a conventionally processed substrate, the wet-etch rate is higher in region 205 than it is in regions outside of region 205. The processed substrate of FIG. 3 has a wet-etch rate uniformity of 14.3 percent, which is undesirably high. Here, wet-etch rate uniformity (wet-etch rate variation) is defined as:
(Maxᵣₐₜₑ−Minᵣₐₜₑ)/(Maxᵣₐₜₑ+Minᵣₐₜₑ)×100%
where Minᵣₐₜₑ is the wet-etch rate of the deposited film at a position outside region 205 of substrate 160 and Maxᵣₐₜₑ is the wet-etch rate of the deposited film at a position on substrate 160 that is inside region 205 of substrate 160. A wet-etch rate typically is proportional to the density of the deposited film. That is, a higher wet-etch rate corresponds to a less dense film. Thus, FIG. 3 suggests that the density of the film in region 205 of substrate 160 is significantly less than the density of the film deposited outside of region 205.

The discontinuity marks that appear in the region where a central lift pin 150 directly supports substrate 160 are often visible to the naked eye as discolored spots. It is believed that these defects are caused by film heterogeneity at positions where the central lift pins 150 contact the substrate. It is appreciated that regions of substrate 160 directly above a central lift pin 150 are subjected to different temperature stresses, thermal expansions, and pressures relative to regions of substrate 160 that are not directly above central lift pins 150.

While discontinuity marks can be avoided in manufacturing schemes that do not require large continuous substrate areas, such as those for PDA or computer screens, the presence of these marks remains undesirable. The discontinuity marks near a substrate center waste processed substrate surface area and therefore increase manufacturing costs. Furthermore, processes designed not to use central portions of processed substrates 160 require additional patterning steps and procedures that increase overall manufacturing time. In applications that require large continuous substrate areas, such as large screen television production, such discontinuity marks simply cannot be avoided. Therefore, the presence of discontinuity marks in such applications impairs product quality.

As outlined above, the use of central lift pins 150 introduces undesirable qualities. Simple removal of center lift pins 150 from conventional lift pin configurations does not provide a solution. When the center lift pins are removed from a conventional pin configuration, such as that shown in FIG. 1, the center of the substrate sags excessively as the substrate is removed from the susceptor. The amount that the substrate sags varies according to the total substrate surface area, the temperature of the substrate and the thickness of the substrate. The substrate is more prone to excessive sag with larger surface areas, thinner substrates, and higher processing temperatures. In typical manufacturing conditions, the temperature is maintained at about 350° C. as the processed substrate is lifted off the susceptor. A substrate with dimensions 600 millimeter×720 millimeter and a thickness of 0.7 millimeter (mm) represents dimensions where excessive sag will begin to appear. A 1100 mm×1250 mm substrate having a thickness of 0.63 mm (e.g., Corning 1737 glass) will sag more than 50 mm in the center using a conventional lift pin configuration in which the central lift pins have been removed. This degree of sag is undesirable. It is difficult to remove a substrate having this amount of sag from a processing chamber using automated lifting assemblies.

Given the above background, what is needed in the art are improved apparatus and methods for lifting substrates out of a processing chamber.

### SUMMARY OF THE INVENTION

The present invention provides lift pin configurations that do not require the use of central lift pins. Accordingly, using the lift pin configurations of the present invention, it is possible to remove a substrate from a processing chamber without introducing discontinuity marks in a central region of the substrate. One embodiment of the present invention provides a method and apparatus for lifting a substrate from a susceptor in a processing chamber. The method comprises (i) positioning each lift pin in a plurality of lift pins on a lift pin holder, and (ii) raising the plurality of lift pins so that they support the substrate. Advantageously, the lift pin configurations of the present invention support a substrate without excessive sag even though the configurations do not require the use of central lift pins.

In the methods and apparatus, the substrate typically has a first dimension that is at least 500 millimeters and a second dimension that is at least 500 millimeters. In some embodiments, the substrate is separated from the susceptor by lowering the susceptor. As the susceptor is lowered, a plurality of lift pins come in contact with the susceptor thereby separating the substrate from the susceptor.

In one embodiment, three lift pins support each edge of the substrate. In another embodiment, the lift pin holder has more than three lift pins (e.g., four lift pins, five lift pins, or more) uniformly positioned on each side of the susceptor. In one aspect of the present invention, all lift pins support the substrate from points within a frame region having a predetermined frame width. The frame region includes the perimeter of the substrate. In some embodiments, the frame width of the frame region is about forty millimeters to about 400 millimeters. In other embodiments, the frame width is less than one-tenth the length or width of the substrate. In some embodiments, the lift pins are configured so that each lift pin support point is at least a predetermined distance from the substrate center. As used herein, lift pin support point is a point of the substrate directly overlying a lift pin. In such embodiments, no lift pin support point is within a central region of the substrate. In some embodiments, the central region of the substrate has a diameter of about 40 millimeters to about 400 millimeters. In other embodiments, the central region of the substrate has diameter that is one-fifth the length of the substrate.

In some embodiments, the distance between each lift pin support point and a closest edge of the substrate is less than one fifth the distance between the lift pin support point and a line bisecting the processed substrate along its width (x axis) or length (y axis). In another embodiment of the present invention, the plurality of lift pins are configured so that the distance between each lift pin support point and a closest edge of the processed substrate is less than one-tenth a length or width of the processed substrate.

Some embodiments use a center assist. In embodiments where a center assist is used, the center assist is retracted either before or soon after the plurality of lift pins have contacted the processed substrate.

In some embodiments, a support member covers the plurality of lift pins. In this way, the support member contacts the substrate in order to separate the substrate from the susceptor. In some embodiments, the support member in fact comprises a plurality of members. Each such member overlies a different subset of the plurality of lift pins.

Advantageously, the substrate that has been processed by the methods and apparatus of the present invention has no discontinuity marks within a central region of the processed substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B depict the lift pin configuration in accordance with the prior art.

FIG. 2 is a graph illustrating differences in film deposition thickness between lift pin support points and other areas of a processed substrate for gate nitride film in accordance with the prior art.

FIG. 3 is a graph illustrating wet etch rate differences between lift pin support points and other areas of a processed substrate for gate nitride film in accordance with the prior art.

FIG. 4 is a cross-sectional view of deposition layers in a chemical vapor deposition (CVD) process in accordance with the prior art.

FIG. 5 is a cross-sectional view of a CVD processing chamber.

FIG. 6 is a cross-sectional view of a CVD processing chamber.

FIG. 7 is a cross-sectional view of a processing chamber illustrating the use of center assists to separate the processed substrate from the susceptor before lifting the processed substrate.

FIG. 8 is a plan view of one embodiment of a lift pin configuration.

FIG. 9 is a plan view of one embodiment an alternative lift pin configuration.

FIG. 10 is a plan view of another embodiment of a lift pin configuration according to one embodiment of the present invention.

FIG. 11 is a plan view of another embodiment a lift pin configuration.

FIG. 12 is a plan view of another embodiment of a lift pin configuration.

### DETAILED DESCRIPTION

The present invention is directed to a method and apparatus for transferring a substrate in and out of a processing chamber. In the embodiments described below, the invention is described with respect to a chemical vapor deposition (CVD) chamber. However, the invention is also applicable to other types of processing chambers. For example, the invention may be used in any chamber that carries out a deposition process. Such chambers include, but are not limited to plasma-enhanced-CVD (PECVD) chambers, etching chambers, physical vapor deposition (PVD) chambers, and rapid thermal annealing (RTA) chambers.

The present invention may be used in a model AKT-3500 PECVD System, manufactured by Applied Materials of Santa Clara, Calif. The AKT-3500 PECVD is designed for use in the production of substrates for large liquid crystal flat panel displays. It is a modular system with multiple process chambers that can be used for depositing amorphous silicon, silicon nitrides, silicon oxides, and oxynitride films. More details regarding the AKT-3500 are found in U.S. Pat. No. 6,432,255 entitled “A Deposition Chamber Cleaning Technique Using a High Power Remote Excitation Source,” assigned to the assignee of the present invention and which is hereby incorporated by reference in its entirety to the extent it is not inconsistent with this application. The present invention may be used with any commercially-available deposition system including, but not limited to a 1600PECVD (e.g. the AKT PECVD 1600 B version, substrate size 400×500), 3500PECVD, 4300PECVD, 5500PECVD, PECVD 10K, PECVD 15K, and PECVD 25K, all manufactured by Applied Materials of Santa Clara, Calif.

As used herein the term “substrate” broadly covers any object that is being processed in a process chamber. The term “substrate” includes, for example, flat panels used for flat panel displays, glass or ceramic plates, and glass or ceramic disks. The present invention is particularly applicable to large substrates, such as glass plates having dimensions 500 mm×500 mm and larger. In one embodiment, the substrate has dimensions 600 mm×720 mm or greater. In another embodiment of the present invention, the substrate has dimensions 1000 mm×1200 mm or greater. In yet another embodiment of the present invention, the substrate has dimensions 1100 mm×1250 mm or greater.

Some embodiments of the present invention are used with substrates having a thickness of about 0.7 mm or greater. Some embodiments of the present invention are used with substrates having a thickness of 0.63 mm or greater. Yet other embodiments of the present invention are used with substrates having a thickness of 0.60 mm or greater. Still other embodiments of the present invention are used with substrates having a thickness of 0.50 mm or greater.

PECVD and CVD are processes used to deposit a thin film layer onto a substrate. Generally in a CVD process, the substrate is supported in a vacuum deposition process chamber and is heated to several hundred degrees Celsius during processing. Deposition gases are injected into the chamber, and a chemical reaction occurs to deposit a thin film layer onto the substrate.

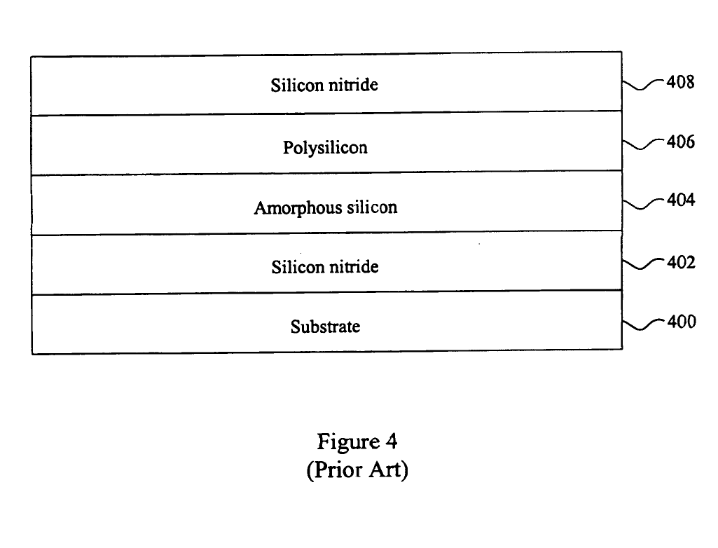

FIG. 4 illustrates an example of typical films deposited during a CVD process. First, a silicon nitride layer 402 is deposited on a substrate 400. Layer 404 is amorphous silicon. The third layer (406) is poly-silicon and the fourth layer (408) is a silicon nitride passivation layer.

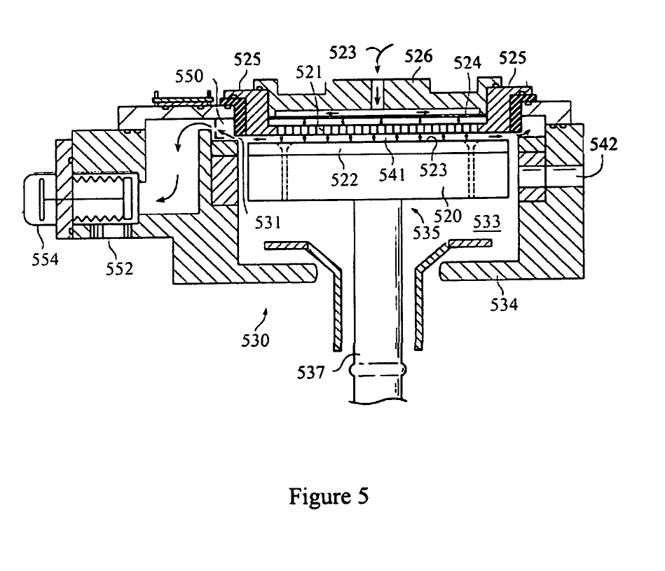

In some embodiments, the deposition process is a PECVD process. FIG. 5 illustrates a PECVD apparatus 530 in which the lift pins of the present invention can be used in order to separate a susceptor from a substrate. As shown in FIG. 5, a PECVD apparatus 530 includes a susceptor 535 having a substrate support plate 520 mounted on a stem 537. Susceptor 535 is shown centered within a vacuum deposition process chamber 533. Support layer 522 is located on support plate 520 to support a substrate such as a glass panel in a substrate processing or reaction region 541. A lift mechanism (not shown) can be provided to raise and lower the susceptor 535. The lift mechanism (not shown) is regulated by commands that are provided by a controller (not shown) using techniques known in the art. Substrates are transferred into and out of chamber 533 through an opening 542 in a sidewall 534 of chamber 533 by a robot blade (not shown).

The deposition process gases (indicated by arrows 523) flow into chamber 533 through inlet manifold 526. The gases then flow through a perforated blocker plate 524 and holes 521 in a process gas distribution faceplate 525. Gas flow direction is indicated with small arrows in the substrate-processing region 541 of FIG. 5. A radio frequency power supply may be used to apply electrical power between gas distribution faceplate 525 and susceptor 535 to excite the process gas mixture and form plasma. The constituents of the plasma react to deposit a desired film on the surface of the substrate on support plate 520 of the susceptor.

In some embodiment of the present invention, susceptor 535 has no lift pin hole in a central portion of the susceptor. In such embodiments, the central portion of susceptor 535 includes a center of the susceptor, and the central portion of the susceptor has an area that is at least 100 mm².

The deposition process gases may be exhausted from the chamber through a slot-shaped orifice 531 surrounding reaction region 541 into an exhaust plenum 550. From exhaust plenum 550, the gases flow through a vacuum shut-off valve 552 and into an exhaust outlet 554 that connects to an external vacuum pump (not shown).

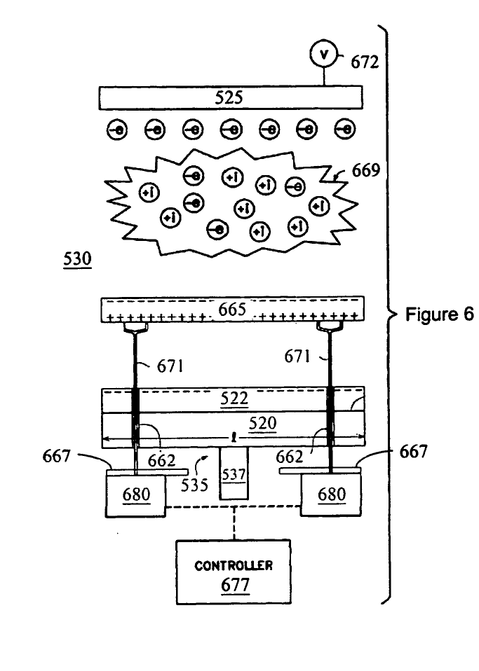

FIG. 6 is a cross-sectional view of processing chamber 530. The figure illustrates the details of substrate support 535 and the plasma 669 used in chamber 530 (FIG. 5). In the illustration, it is seen that RF power supply 672 provides power to a gas distribution faceplate 525. Plasma 669 is generated between faceplate 525 and susceptor 535.

As discussed above, a robot blade facilitates the transfer of substrates into and out of chamber 530 through an opening 542 in sidewall 534 of chamber 533 (FIG. 5). Referring to FIG. 6, once the robot blade (not shown) moves substrate 665 into position, lift pins 671, which are positioned on lift pin holders 667, move upward to support substrate 665 prior to moving the substrate into a processing position. In particular, lift pins 671 move through lift pin holes 662 of susceptor 535 to contact and support substrate 665. Lift pins 671 may move through lift pin holes 662 by the action of a lift means 680 using known translation mechanisms or linear feedthroughs.

It should be noted that in some processing chambers, such as the AKT-1600 PECVD system (Applied Materials, Santa Clara, Calif.), the substrate is moved into a processing position due to the movement of susceptor 535. After the robot blade (not shown) moves substrate 665 onto lift pins 671, susceptor 535 then moves upwards to contact substrate 665.

Some embodiments of the present invention use alumina lift pins as lift pins 671. Alumina lift pins are commercially available as product number 0200-71597 Rev. E1, identification number 11875000 (Stratamet, Inc., Fremont, Calif.).

Advantageously, lift pins 671 of the present invention do not support substrate 665 at support points in the central region of substrate 665. In one definition, the central region of substrate 665 is defined as the area within a predetermined distance (e.g., 100 mm, 200 mm, or greater) from the center of substrate 665. Rather than using center lift pins, the lift pins of the present invention support the substrate from support points in a frame portion of substrate 665. Frame portion 665 includes the substrate perimeter.

In the present invention, after lift pins 671 have contacted substrate 665, the robot blade is withdrawn and substrate 665 is brought into position for processing. One method of positioning substrate 665 so that it lies flat against the susceptor is described in U.S. patent application Ser. No. 08/990,743, assigned to the assignee of the present invention and incorporated herein by reference.

After the desired chemicals are deposited as one or more films on processed substrate 665, the substrate is separated from susceptor 535 and then lifted out of the deposition chamber. One way to separate susceptor 535 from substrate 665 is described in U.S. Pat. No. 5,380,566, assigned to the assignee of the present invention and incorporated herein by reference. The method involves subjecting the processed substrate to plasma of an inactive gas 669 (FIG. 6) (e.g., hydrogen, nitrogen, argon or ammonia) that does not adversely affect the film on substrate 665 and does not add additional layers to the film already on substrate 665. Electrical charge interactions between plasma 669 and substrate 665 help to loosen the bond between the substrate and susceptor 535. Lift pins 671 are then used to raise substrate 665 away from susceptor 535. In some embodiments, plasma 669 is no longer used when lift pins 671 raise substrate 665 away from susceptor 535. In other embodiments, plasma 669 is used even after lift pins 671 have raised substrate 665 away from susceptor 535 (as illustrated in FIG. 6). In FIG. 6, plasma 669 is shown in the chamber at a time when substrate 665 has been raised by lift pins 671 away from susceptor 535. Although not illustrated in FIG. 6, plasma 669 is used in some embodiments when substrate 665 is on susceptor 535 in order to help dislodge the substrate from the susceptor before using lift pins 671 to raise the substrate.

After the desired film has been deposited onto substrate 665, lifting mechanism 680 raises lift pins 671 so that they move through lift pin holes 662 and contact processed substrate 665. Lifting mechanism 680 is controlled by controller 677. Note that in some processing chambers not illustrated, such as the AKT-1600 PECVD, downward movement of the susceptor effectively lifts the processed substrate away from the susceptor. As the susceptor is lowered, the lift pins contact the processed substrate and support the substrate.

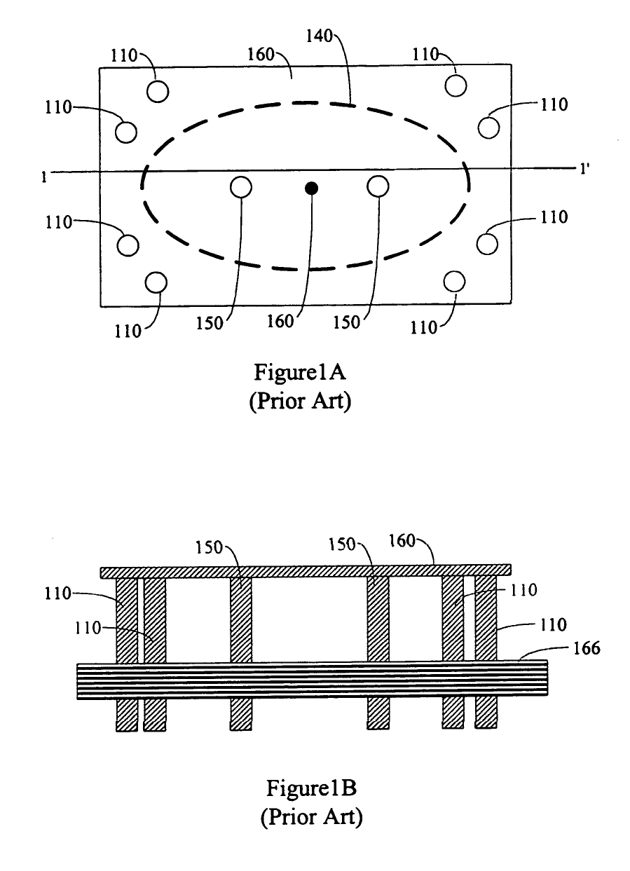

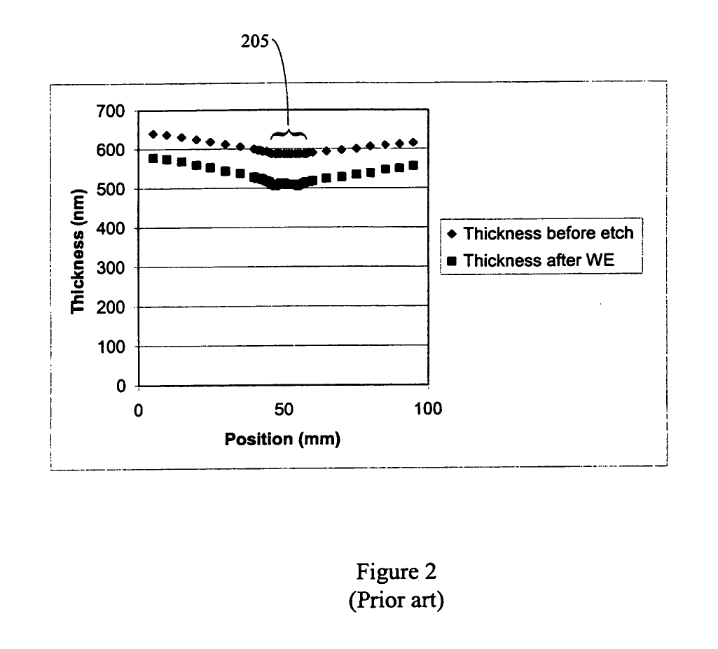

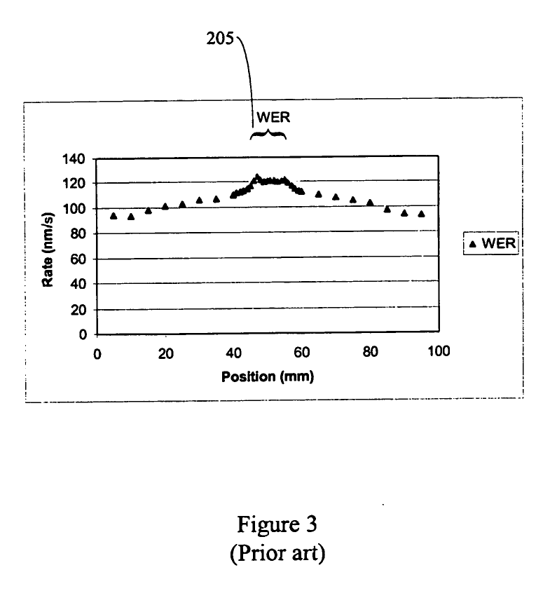

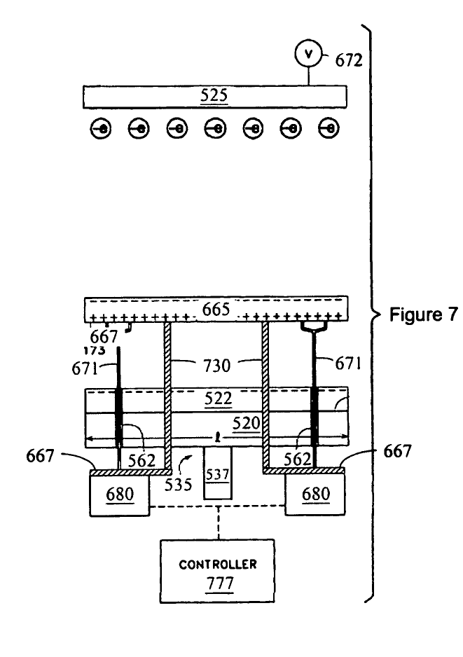

FIG. 7 presents an alternate method for separating the substrate from the susceptor before the processed substrate is lifted in accordance with the present invention. Center assists 730 contact processed substrate 665 near the center of the substrate and force substrate 665 off the support layer 522 of susceptor 535 before retracting. Commands are sent to center assists 730 by controller 777 using techniques known in the art. Centers assists 630 (FIG. 7) differ from central lift pins 150 (FIG. 1) in the sense that the center assists 630 are used to nudge substrate 665 off of susceptor 535 rather than to support the substrate. As such, in a typical embodiment, center assists 630 briefly contact substrate 665 in order to knock the substrate off the susceptor. Then, the center assists are withdrawn and lift pins on the perimeter of the substrate are used to raise the substrate away from the susceptor so that a robot blade can be slid underneath the substrate. Once the robot blade contacts the substrate, the blade is used to remove the substrate from the deposition chamber.

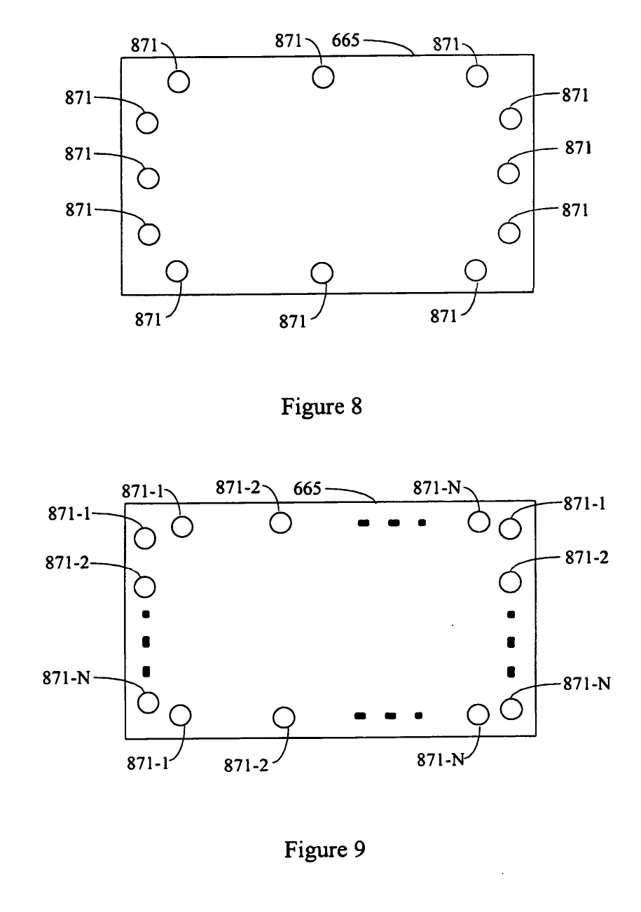

It has been unexpectedly discovered that the configuration of lift pins illustrated in FIG. 8 support a substrate 665 without the use of center lift pins. The configuration of lift pins illustrated in FIG. 8 differs from known lift pin configurations such as that disclosed in FIG. 1. In FIG. 8, a third lift pin is present on each side of the substrate. The presence of the third lift pin on each side of the substrate in FIG. 8 provides sufficient support to separate substrate 665 from the susceptor without causing the substrate to sag excessively. In some embodiments, lift pins 871 on each edge of processed substrate 665 are equally spaced.

FIG. 9 is a plan view of another configuration of lift pins 871 in accordance with the present invention. In the configuration shown in FIG. 9, each side of substrate 665 is supported by N lift pins 871, where N is three, four, five, six, or an integer larger than six. In some embodiments, lift pins 871 are equally spaced along each side of substrate 665.

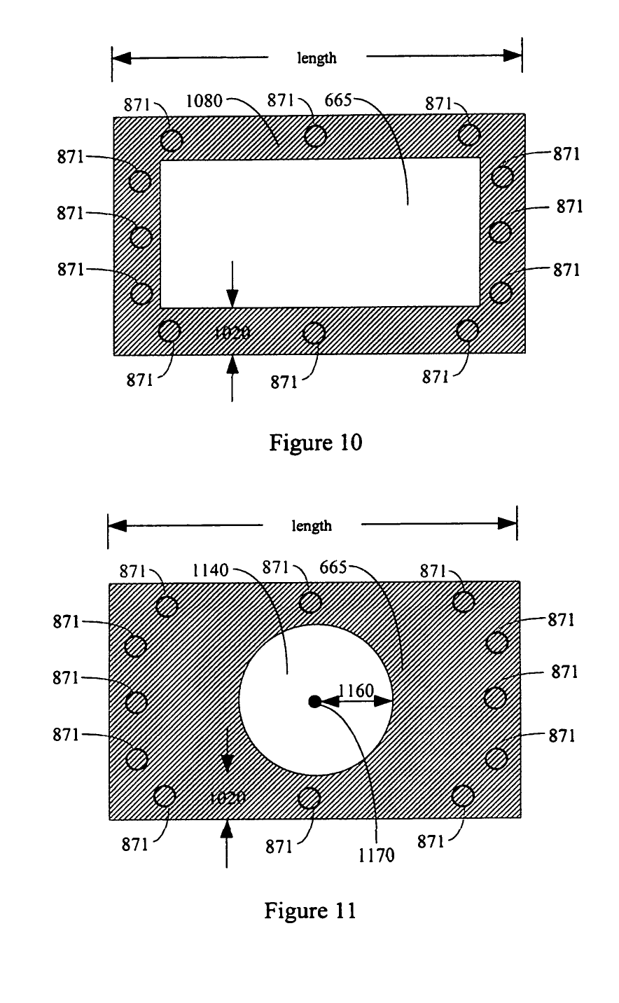

FIG. 10 is a plan view of another configuration of the present invention. Lift pins 871 support a substrate 665. Each lift pin 871 supports substrate 665 at a particular point on the substrate that corresponds to the lift pin 871. The point at which a lift pin 871 supports a substrate 665 is defined herein as the lift pin support point. All lift pin support points in the embodiment shown in FIG. 10 lie within a frame portion 1080 of substrate 665. In some embodiments of the present invention, frame portion 1080 has a pre-determined width 1020. In one embodiment, the pre-determined frame width is about 40 millimeters to about 400 millimeters. In another embodiment, the pre-determined width of frame portion 1080 is about one-tenth the longer dimension of substrate 665 or less. Thus, for a substrate having dimensions 600 millimeters×720 millimeters, the frame width is about 72 millimeters or less. In some embodiments, the pre-determined width of frame portion 1080 is about one-fifth the length or width of substrate 665 or less. In some embodiments, the width of frame portion 1080 is different on each side of substrate 1080. Although FIG. 10 shows a lift pin configuration with three equally spaced lift pins 871 supporting each edge of the substrate 665, other lift pin configurations that support substrate 665 within frame portion 1080 are possible. For example, the lift pin configuration of FIG. 9 could be used, where each lift pin 871-N (FIG. 9) lies within frame region 1080.

FIG. 11 is a plan view of another configuration of lift pins 871 in accordance with the present invention. Each lift pin support point is at least a predetermined distance from center 1170 of processed substrate 665. In FIG. 11, lift pins 871 are shown supporting processed substrate 665 such that all the lift pin support points are at least a pre-determined distance 1160 from substrate center 1110. In other words, no lift pin support point is within region 1140 (center portion) of the substrate. In one embodiment, the predetermined distance 1160 is about 100 millimeters or more, about 120 millimeters or more, about 200 millimeters or more, or about 400 millimeters or more. In another embodiment, predetermined distance 1160 is about one-fifth the longer dimension of the substrate. Thus, for a substrate with dimensions 1100 mm×1250 mm, the predetermined distance is 250 mm. In some embodiments, the pre-determined distance 1160 is about one-fifth the length or width of substrate 665. In some embodiments, no lift pin is within center region 1140 (FIG. 11) of substrate 665 and center region 1140 has a diameter of at least 100 millimeters. In some embodiments, no lift pin is within center region 1140 (FIG. 11) of substrate 665 and center region 1140 has a diameter of at least 200 millimeters. Although FIG. 11 shows a lift pin configuration with three equally spaced lift pins 880 supporting each edge of the substrate 1100, other lift pin configurations outside the center region are possible. For example, the lift pin configuration illustrated in FIG. 9 could be used.

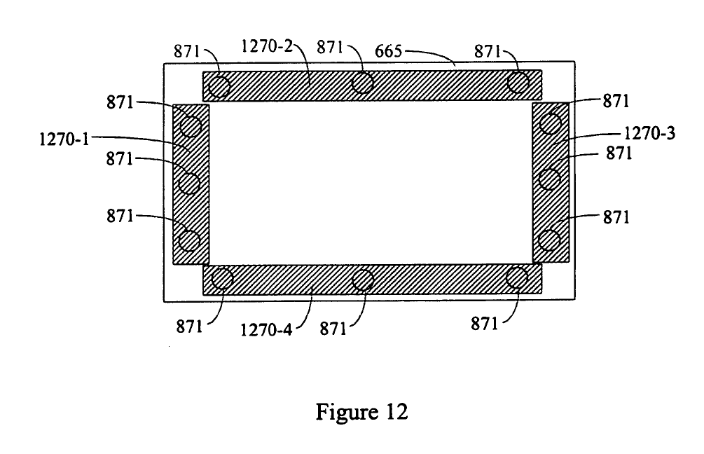

FIG. 12 is a plan view of another embodiment of the present invention. Substrate 665 is shown supported by lift pins 871. A support member 1270 overlies at least a subset of the lift pins and contacts the substrate when the lift pins are used to separate the substrate from the susceptor. As illustrated in FIG. 12, support member 1270-1 overlies a subset of lift pins 1371. Similarly, support members 1270-2, 1270-3, and 1270-4 overly different subsets of lift pins 871. Various numbers, configurations and sizes of overlying support members 1270 are possible in accordance with the present invention.

While the foregoing is directed to embodiments of the present invention, other and further embodiments of the invention may be devised without departing from the basic scope thereof, and the scope thereof is determined by the claims that follow.

1. A method of lifting a substrate from a susceptor in a processing chamber, the method comprising:
contacting a perimeter of the substrate with a plurality of lift pins;
contacting a center of the substrate with at least one center assist; and
retracting the at least one center assist when the substrate is spaced apart from the susceptor.

2. The method of claim 1 wherein said substrate has a first dimension that is at least 500 millimeters and a second dimension that is at least 500 millimeters.

3. The method of claim 1 wherein the plurality of lift pins support the substrate when a susceptor is lowered below a tip of a lift pin in said plurality of lift pins.

4. The method of claim 1 wherein each lift pin in said plurality of lift pins is configured so that it supports the substrate from a point that is at least 120 millimeters from a center of the substrate.

5. The method of claim 1 wherein the plurality of lift pins is configured so that each lift pin in said plurality of lift pins supports the substrate from a point in a frame portion of the substrate, the frame portion including a perimeter of said substrate and the frame portion having a width that is less than about forty millimeters.

6. The method of claim 1 wherein the plurality of lift pins are configured so that each lift pin supports the substrate at a lift pin support point and wherein there are at least three lift pin support points on an edge of the substrate.

7. The method of claim 1 wherein the plurality of lift pins are configured so that each lift pin supports the substrate at a lift pin support point and the distance between each lift pin support point and a closest edge of the substrate is less than one-fifth a length or width of the substrate.

8. The method of claim 1 wherein the plurality of lift pins are configured so that each lift pin supports the substrate at a corresponding lift pin support point and no pin in said plurality of lift pins has a corresponding lift pin support point in a center region of the substrate.

9. The method of claim 8 wherein said center region of said substrate has a diameter of at least 100 millimeters.

10. The method of claim 8 wherein said center region of said substrate has a diameter of at least 200 millimeters.

11. The method of claim 1, the method further comprising subjecting the substrate to a plasma.

12. The method of claim 1, wherein the substrate comprises glass.

13. A method of processing a substrate without creating discontinuity marks in a center region of said substrate, the method comprising:
depositing a layer on said substrate when the substrate is on a susceptor in a deposition chamber;
separating the substrate from the susceptor; and
lifting the substrate from the susceptor by engaging a plurality of lift pins that contact the substrate at a perimeter, wherein no lift pin contacts the substrate within said center region of said substrate.

14. The method of claim 13 wherein said center region has a diameter of at least 200 millimeters and includes a center of said substrate and wherein said frame portion has a width of less than one-tenth a length or width of said substrate.

15. A method of lifting a substrate from a susceptor in a processing chamber, the method comprising:
using a plurality of lift pins to support the substrate, wherein said plurality of lift pins does not include a center lift pin and wherein the plurality of lift pins are configured so that each lift pin supports the substrate at a lift pin support point and the distance between each lift pin support point and a closest edge of the substrate is less than one-fifth a length or width of the substrate.

16. The method of claim 15, wherein said substrate has a first dimension that is at least 500 millimeters and a second dimension that is at least 500 millimeters.

17. The method of claim 15, wherein the plurality of lift pins support the substrate when a susceptor is lowered below a tip of a lift pin in said plurality of lift pins.

18. The method of claim 15, wherein the plurality of lift pins is configured so that each lift pin in said plurality of lift pins supports the substrate from a point in a frame portion of the substrate, the frame portion including a perimeter of said substrate and the frame portion having a width that is less than about forty millimeters.

19. The method of claim 15, wherein the plurality of lift pins are configured so that each lift pin supports the substrate at a lift pin support point and wherein there are at least three lift pin support points.

20. The method of claim 1, the method further comprising contacting the substrate with a center assist.
